(19) United States
(12) Patent Application Publication
(10) Pub. No.: US 2024/0402589 A1
(43) Pub. Date: Dec. 5, 2024

(54) MASK BLANK SUBSTRATE, SUBSTRATE WITH MULTILAYER REFLECTIVE FILM, MASK BLANK, AND TRANSFER MASK

(71) Applicant: HOYA CORPORATION, Tokyo (JP)

(72) Inventors: Hideaki NARAHARA, Tokyo (JP); Takashi UCHIDA, Tokyo (JP)

(73) Assignee: HOYA CORPORATION, Tokyo (JP)

(21) Appl. No.: 18/270,178

(22) PCT Filed: Dec. 14, 2021
(86) PCT No.: PCT/JP2021/046020

§ 371 Date: Jun. 24, 2024

(30) Foreign Application Priority Data
Jan. 5, 2021 (JP) 2021-000517

(51) Int. Cl. G03F 1/60; G03F 1/24

(52) U.S. Cl. CPC G03F 1/60; G03F 1/24

(57) ABSTRACT

Provided is a substrate for mask blank, a substrate with multilayer reflective film, and a mask blank

The substrate for mask blank has two opposing main surfaces. In an inner region of a square having a side of 132 mm based on the center of the substrate, a synthetic surface profile is produced from surface profiles of the two main surfaces of the substrate, a relationship between spatial frequency fr[mm⁻¹] and power spectral density Pr[μm²/(mm⁻¹)] is calculated from the synthetic surface profile, and within the range of spatial frequency fr of 0.02 [mm⁻¹] or more and 0.40 [mm⁻¹] or less, a relationship Pr<(1.5141×10⁻⁶)× (fr^{-1.3717}) is satisfied in at least 75% or more spatial frequencies fr.

### CROSS-REFERENCE TO RELATED APPLICATIONS

This application is the National Stage of International Application No. PCT/JP2021/046020, filed Dec. 14, 2021, which claims priority to Japanese Patent Application No. 2021-000517, filed Jan. 5, 2021, and the contents of which is incorporated by reference.

### TECHNICAL FIELD

The present disclosure relates to a substrate for a mask blank, a substrate with a multilayer reflective film, a mask blank, a method of manufacturing a transfer mask, and a method of manufacturing a semiconductor device, and particularly to a substrate for a mask blank, a substrate with a multilayer reflective film, a mask blank, a method of manufacturing a transfer mask for use in EUV lithography, and a method of manufacturing a semiconductor device.

### BACKGROUND ART

Generally, at the steps of manufacturing a semiconductor device, fine patterns are formed using a photolithography method. To form the fine patterns, many transfer masks called photomasks are usually used. The transfer mask is generally formed by providing a fine pattern made of a metal thin film or the like on a transparent glass substrate, and the photolithography method is also used in the manufacture of the transfer mask.

Regarding the types of transfer masks, a phase shift mask is known in addition to a binary mask having a light shielding pattern made of a chromium-based material on a known transparent substrate. The phase shift mask has a structure in which a phase shift film is formed on a transparent substrate, and the phase shift film has a predetermined phase difference and is made of, for example, a material containing a molybdenum silicide compound. A binary mask using a material containing a silicide compound of a metal such as molybdenum for a light shielding film has also been used. The binary mask and the phase shift mask may be collectively referred to as a transmissive mask, and a binary mask blank and a phase shift mask blank which are original plates used for the transmissive mask may be collectively referred to as a transmissive mask blank.

In recent years, in the semiconductor industry, highly integrated semiconductor devices are required to have a fine pattern with precision exceeding the transfer limit of the known photolithography method using ultraviolet light. EUV lithography, which is an exposure technique using extreme ultraviolet (hereinafter, referred to as “EUV”) light, offers great promise for forming such a fine pattern. The EUV light refers to light in a wavelength band of a soft X-ray region or a vacuum ultraviolet region, specifically light having a wavelength from about 0.2 nm to 100 nm. A reflective mask has been proposed as a transfer mask used in the EUV lithography. In such a reflective mask, a multilayer reflective film for reflecting exposure light is formed on a substrate, and an absorber film for absorbing exposure light is formed in a pattern on the multilayer reflective film.

The reflective mask is manufactured by forming an absorber pattern by a photolithography method or the like from a reflective mask blank which includes a substrate, a multilayer reflective film formed on the substrate, and an absorber film formed on the multilayer reflective film.

As a substrate for a mask blank used in the manufacture of such a reflective mask, for example, a substrate for a mask blank disclosed in Patent Document 1 is known. To suppress the detection of pseudo defects, the substrate for a mask blank disclosed in Patent Document 1 has a structure in which a power spectral density at a spatial frequency from 1×10⁻² μm⁻¹ to 1 μm⁻¹ is 4×10⁶ nm⁴ or less, where the spatial frequency is obtained by measuring, with a white light interferometer with a resolution of 640×480 pixels, a region of 0.14 mm×0.1 mm of a main surface of the substrate for a mask blank on a side where the transfer pattern is to be formed, and a power spectral density at a spatial frequency of 1 μm⁻¹ or more is 10 nm⁴ or less, where the spatial frequency is obtained by measuring a region of 1 μm×1 μm of the main surface with an atomic force microscope.

### Prior Art Publications

### Patent Documents

Patent Document 1 JP 5712336 B

### SUMMARY OF THE DISCLOSURE

### Problems to be Solved by the Disclosure

Exposure apparatuses for manufacturing semiconductor devices have advanced while the wavelength of a light source is gradually shortening. To implement finer pattern transfer, EUV lithography using EUV light having a wavelength of about 13.5 nm has been developed. To implement such fine pattern transfer, a substrate for a mask blank is required to have a high degree of flatness. In a case where the flatness of a reflective mask blank is deteriorated, when a transfer pattern of a reflective mask produced from the reflective mask blank is transferred onto a wafer, the image forming position of a pattern deviates from a wafer surface, so that the pattern transfer precision is reduced and the dimensions of a circuit pattern formed on the wafer deviate, resulting in a problem that a semiconductor device having expected performance may not be obtained. Furthermore, in a case where the flatness of the reflective mask blank deteriorates, when the transfer pattern of the reflective mask is transferred onto the wafer, a pattern formation position deviates from the desired position, resulting in a problem that a semiconductor device in which a transistor thereof can exhibit expected characteristics regarding a switching speed, a leakage current, and the like may not be obtained. The amount of deviation of the pattern formation position from the desired position is called overlay precision (superposition precision), and as the circuit dimensions of a semiconductor device become smaller, smaller superposition precision is required.

However, it has been found that even in the case of a known substrate satisfying the requirements regarding flatness or the like, desired overlay precision may not be obtained in a reflective mask produced from the substrate.

Therefore, an aspect of the present disclosure is to provide a substrate for a mask blank, a substrate with a multilayer reflective film, and a mask blank from which a transfer mask that can satisfy desired overlay precision, can be manufactured.

Another aspect of the present disclosure is to provide a method of manufacturing a transfer mask manufactured using the above mask blank, and a method of manufacturing a semiconductor device using a transfer mask, manufactured by the method of manufacturing a transfer mask.

### Means for Solving the Problem

The present disclosure has been made to solve the above problems, and has the following configurations.

### Configuration 1

A substrate for a mask blank, the substrate including two main surfaces opposing each other, in which when a synthetic surface profile is produced from surface profiles of the two main surfaces of the substrate in an inner region of a square having a side of 132 mm based on a center of the substrate and a relationship between a spatial frequency fr[mm⁻¹] and a power spectral density Pr[μm²/(mm⁻¹)] is calculated from the synthetic surface profile, a relationship of Pr<(1.5141×10⁻⁶)×(fr^{-1.3717}) is satisfied at at least 75% or more of the spatial frequencies fr in a range of the spatial frequency fr from 0.02 [mm⁻¹] to 0.40 [mm⁻¹].

### Configuration 2

The substrate for a mask blank according to configuration 1, in which the synthetic surface profile is obtained by adding the surface profile of one main surface, which is an in-plane distribution of a height from a reference surface which is a reference of the surface profile of the one main surface to the one main surface, and the surface profile of the other main surface, which is an in-plane distribution of a height from a reference surface which is a reference of the surface profile of the other main surface to the other main surface.

### Configuration 3

The substrate for a mask blank according to configuration 1 or 2, in which the power spectral density Pr is calculated at an interval of the spatial frequency fr of 1.0×10⁻² [mm⁻¹] or less.

### Configuration 4

A substrate with a multilayer reflective film including a multilayer reflective film provided on the one main surface of the substrate for a mask blank according to any one of configurations 1 to 3.

### Configuration 5

A substrate with a multilayer reflective film, the substrate including a substrate having two main surfaces opposing each other, the multilayer reflective film is provided on one main surface, and a conductive film is provided on the other main surface, in which when a synthetic surface profile is produced from a surface profile of the multilayer reflective film and a surface profile of the conductive film in an inner region of a square having a side of 132 mm based on a center of the substrate and a relationship between a spatial frequency fr[mm⁻¹] and a power spectral density Pr[μm²/(mm⁻¹)] is calculated from the synthetic surface profile, a relationship of Pr< (1.5141×10⁻⁶)×(fr^{-1.3717}) is satisfied at at least 75% or more of the spatial frequencies fr in a range of the spatial frequency fr from 0.02 [mm⁻¹] to 0.40 [mm⁻¹].

### Configuration 6

The substrate with a multilayer reflective film according to configuration 5, in which the synthetic surface profile is obtained by adding the surface profile of the multilayer reflective film, which is an in-plane distribution of a height from a reference surface which is a reference of the surface profile of the multilayer reflective film to a surface of the multilayer reflective film, and the surface profile of the conductive film, which is an in-plane distribution of a height from a reference surface which is a reference of the surface profile of the conductive film to a surface of the conductive film.

### Configuration 7

The substrate with a multilayer reflective film according to configuration 5 or 6, in which the power spectral density Pr is calculated at an interval of the spatial frequency fr of 1.0×10⁻² [mm⁻¹] or less.

### Configuration 8

A mask blank including a pattern forming thin film provided on the multilayer reflective film of the substrate with a multilayer reflective film according to any one of configurations 5 to 7.

### Configuration 9

A mask blank including a pattern forming thin film provided on one main surface of two main surfaces of a substrate including the two main surfaces opposing each other, and a conductive film provided on the other main surface of the two main surfaces, in which when a synthetic surface profile is produced from a surface profile of the pattern forming thin film and a surface profile of the conductive film in an inner region of a square having a side of 132 mm based on a center of the substrate and a relationship between a spatial frequency fr[mm⁻¹] and a power spectral density Pr[μm²/(mm⁻¹)] is calculated from the synthetic surface profile, a relationship of Pr< (1.5141×10⁶)×(fr^{-1.3717}) is satisfied at at least 75% or more of the spatial frequencies fr in a range of the spatial frequency fr from 0.02 [mm⁻¹] to 0.40 [mm⁻¹].

### Configuration 10

The mask blank according to configuration 9, in which the synthetic surface profile is obtained by adding the surface profile of the pattern forming thin film, which is an in-plane distribution of a height from a reference surface which is a reference of the surface profile of the pattern forming thin film to a surface of the pattern forming thin film, and the surface profile of the conductive film, which is an in-plane distribution of a height from a reference surface which is a reference of the surface profile of the conductive film to a surface of the conductive film.

### Configuration 11

The mask blank according to configuration 9 or 10, in which the power spectral density Pr is calculated at an interval of the spatial frequency fr of 1.0×10⁻² [mm⁻¹] or less.

### Configuration 12

The mask blank according to any one of configurations 9 to 11 including a multilayer reflective film between the one main surface and the pattern forming thin film.

### Configuration 13

A method of manufacturing a transfer mask, the method including the step of:
forming a transfer pattern in the pattern forming thin film of the mask blank according to any one of configurations 9 to 12.

### Configuration 14

A method of manufacturing a semiconductor device, the method including the step of:
setting, on a mask stage of an exposure apparatus, the transfer mask manufactured by the method of manufacturing the transfer mask according to configuration 13; and
pattern-transferring a transfer pattern of the transfer mask onto a semiconductor substrate by a lithography method.

### Effect of the Disclosure

According to the present disclosure, it is possible to provide a substrate for a mask blank, a substrate with a multilayer reflective film, and a mask blank that can satisfy desired overlay precision required for a produced mask. It is also possible to provide a method of manufacturing a transfer mask manufactured using the above mask blank, and a method of manufacturing a semiconductor device using a transfer mask manufactured by the method of manufacturing a transfer mask.

### BRIEF DESCRIPTION OF THE DRAWINGS

FIG. 1 is a cross-sectional view of a substrate for a mask blank, a substrate with a multilayer reflective film, and a mask blank according to an embodiment of the present disclosure.

FIG. 2 is a graph showing an average value of power spectral density of an OK substrate, an average value of power spectral density of an NG substrate, and an approximate curve (threshold curve) calculated from an average value of power spectral density of an NG substrate with respect to a spatial frequency.

FIG. 3 is a graph showing a curve of power spectral density in a substrate for a mask blank of Example 1 and a threshold curve with respect to spatial frequency.

FIG. 4 is a graph showing a curve of power spectral density in a substrate for a mask blank of Example 2 and a threshold curve with respect to spatial frequency.

FIG. 5 is a graph showing a curve of power spectral density in a substrate for a mask blank of Example 3 and a threshold curve with respect to spatial frequency.

FIG. 6 is a graph showing a curve of power spectral density in a substrate for a mask blank of Comparative Example 1 and a threshold curve with respect to spatial frequency.

FIG. 7 is a graph showing a curve of power spectral density in a substrate for a mask blank of Comparative Example 2 and a threshold curve with respect to spatial frequency.

FIG. 8 is a graph showing a curve of power spectral density in a substrate for a mask blank of Comparative Example 3 and a threshold curve with respect to spatial frequency.

### EMBODIMENTS FOR CARRYING OUT THE DISCLOSURE

Hereinafter, embodiments of the present disclosure will be described, and first, the background of the present disclosure will be described. First, the present inventors collected a predetermined number (approximately 100) of substrates for a mask blank satisfying desired overlay precision (hereinafter, referred to as “OK substrates” as appropriate) and a predetermined number (approximately 100) of substrates for a mask blank not satisfying the desired overlay precision (hereinafter, referred to as “NG substrates” as appropriate) among substrates for a mask blank satisfying desired flatness, and conducted intensive studies on each of them. First, the present inventors have focused on a synthetic surface profile obtained from the surface profiles of two main surfaces of a substrate for a mask blank in an inner region (region where a transfer pattern is to be formed) of a square having a side of 132 mm based on the center of the substrate. This is because when a transfer mask manufactured using the substrate for a mask blank is set (chucked) in an exposure apparatus, the main surface on the chucked side has a substantially flat shape, and the surface profile of the chucked main surface is added to the surface profile of an exposed main surface.

Next, the present inventors have focused on the relationship between a spatial frequency fr[mm⁻¹] and a power spectral density Pr[μm²/(mm⁻¹)] calculated in a wide region that is the inner region of the square having a side of 132 mm based on the center of the substrate, with respect to the synthetic surface profiles of the OK substrate and the NG substrate described above. This makes it possible to obtain a profile component having a larger period (smaller spatial frequency), which was not obtained in the related art.

Then, the present inventors have found that for each of the OK substrates and each of the NG substrates, when the power spectral density with respect to the spatial frequency was calculated in the inner region of the square having a side of 132 mm based on the center of the substrate and the average value of the power spectral density was calculated for each of the OK substrates and each of the NG substrates, there is a significant difference in the power spectral density Pr[μm²/(mm⁻¹)] between the OK substrate and the NG substrate in the range of the spatial frequency fr from 0.02 [mm⁻¹] to 0.40 [mm⁻¹].

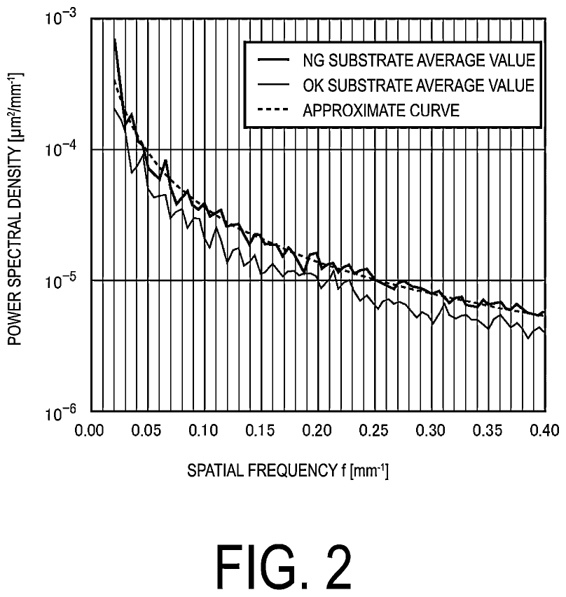

Therefore, the present inventors have conducted more detailed studies on these ranges. First, the average value of the power spectral density of all the OK substrates satisfying the desired overlay precision was calculated for each spatial frequency, and the tendency of the relationship between the spatial frequency and the power spectral density of the OK substrate was obtained. Next, the average value of the power spectral density of all the NG substrates not satisfying the desired overlay precision was calculated for each spatial frequency, and the tendency of the relationship between the spatial frequency and the power spectral density of the NG substrate was obtained. Moreover, an approximate curve (threshold curve) was calculated from the relationship between the spatial frequency and the power spectral density of the NG substrate. The results are shown in FIG. 2. As shown in FIG. 2, it can be seen that the average value Pr[μm²/(mm⁻¹)] of the power spectral density of the OK substrate is significantly lower than the average value Pr[μm²/(mm⁻¹)] of the power spectral density of the NG substrate in the range of the spatial frequency fr from 0.02 [mm⁻¹] to 0.40 [mm⁻¹]. Then, as shown in FIG. 2, the present inventors calculated an approximate curve by using power approximation with respect to the relationship between the spatial frequency and the power spectral density Pr[μm²/(mm⁻¹)] of the NG substrate to obtain a threshold curve Pr (=(1.5141×10⁻⁶)×(fr^{-1.3717})). Then, in the range of the spatial frequency fr from 0.02 [mm⁻¹] to 0.40 [mm⁻¹], the present inventors examined the magnitude relationship between the power spectral density Pr[μm²/(mm⁻¹)] of the threshold curve and the power spectral density Pr[μm²/(mm⁻¹)] in the OK substrate.

As a result, the present inventors found that for any of the OK substrates, the relationship of Pr< (1.5141×10⁻⁶)× (fr^{-1.3717}) is satisfied at 75% of more of the spatial frequencies fr in the range of the spatial frequency fr from 0.02 [mm⁻¹] to 0.40 [mm⁻¹]. As long as the above relationship is satisfied, there is no problem even though the synthetic surface profile of the substrate has a high power spectral density in a low spatial frequency (long wavelength) region of less than 0.02 [mm⁻¹]. This is because an exposure transfer image can be easily corrected by a correction function of an exposure apparatus even when a transfer mask manufactured from such a substrate is set in the exposure apparatus and exposure transfer is performed.

Based on the above intensive studies, the present disclosure has been completed.

Hereinafter, the best mode for carrying out the present disclosure will be specifically described below: including its concept, with reference to the drawings.

### Substrate for Mask Blank and Method of Manufacturing the Same

Hereinafter, a substrate for a mask blank and a method of manufacturing the same will be described. In the present embodiment, a substrate for a mask blank for use in EUV lithography will be described; however, a substrate for a mask blank of the present disclosure is not limited thereto and can also be applied to, for example, a substrate for a mask blank for use in transmissive optical lithography.

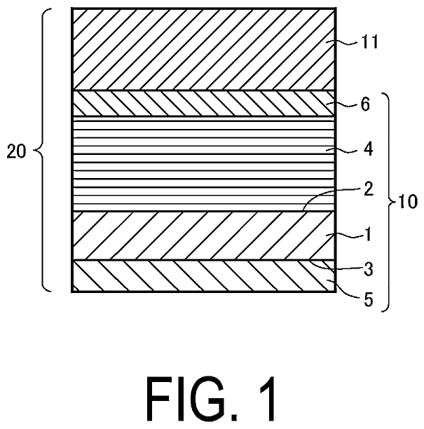

FIG. 1 illustrates a substrate 1 for a mask blank according to an embodiment of the present disclosure. As illustrated in FIG. 1, to prevent distortion of a transfer pattern (not illustrated) due to heat during exposure using EUV light, the substrate 1 with a low coefficient of thermal expansion in the range of 0═5 ppb/° C., is preferably used. As the materials having a low coefficient of thermal expansion in this range. SiO₂—TiO₂-based glass, multicomponent-based glass ceramics, or the like can be used.

The substrate 1 has two main surfaces 2 and 3 opposing each other. The main surface 2 of the substrate 1 on which a transfer pattern is to be formed is subjected to a surface treatment in order to achieve a high degree of flatness from the viewpoint of obtaining at least pattern transfer precision and positioning precision. In the case of EUV exposure, the flatness is preferably 0.1 μm or less, more preferably 0.05 μm or less, and particularly preferably 0.03 μm or less in a region of 132 mm×132 mm of the main surface 2 of the substrate 1, on which the transfer pattern is to be formed, based on the center of the substrate 1. The main surface 3 opposite to the side on which the transfer pattern is to be formed is a surface that is to be electrostatically chucked when set in an exposure apparatus, and the flatness is preferably 0.1 μm or less, more preferably 0.05 μm or less, and particularly preferably 0.03 μm or less in the 132 mm×132 mm region. Note that the flatness of the main surface 3 side in a reflective mask blank 20 is preferably 1 μm or less, more preferably 0.5 μm or less, and particularly preferably 0.3 μm or less in a region of 142 mm×142 mm.

In the substrate 1 according to the present embodiment, when a synthetic surface profile is produced from the surface profiles of the two main surfaces 2 and 3 of the substrate 1 in an inner region of a square having a side of 132 mm based on the center of the substrate 1 and the relationship between a spatial frequency fr[mm⁻¹] and a power spectral density Pr[μm²/(mm⁻¹)] is calculated from the synthetic surface profile, the relationship of Pr< (1.5141×10⁶)×(fr^{1.3717}) is satisfied at at least 75% or more of the spatial frequencies fr in the range of the spatial frequency fr from 0.02 [mm⁻¹] to 0.40 [mm⁻¹].

The synthetic surface profile is obtained by adding the surface profile of the one main surface 2, which is an in-plane distribution of a height from a reference surface which is the reference of the surface profile of the one main surface 2 to the one main surface 2, and the surface profile of the other main surface 3, which is an in-plane distribution of a height from a reference surface which is the reference of the surface profile of the other main surface 3 to the other main surface 3.

Each of the surface profiles of the main surfaces 2 and 3 is acquired by a surface profile measuring apparatus. The surface profile measuring apparatus arranges measurement points on a surface of a measurement target in a grid pattern and acquires a surface profile in the form of height information of each measurement point. The reference surface is a plane (least square plane) approximated by a least square method on the basis of the height information of each measurement point. The reference surface of the main surface 2 and the reference surface of the main surface 3 may not be parallel to each other. In such a case, the produced synthetic surface profile includes an error of a tilt component. However, this error has substantially no influence on the numerical value of the power spectral density Pr at the spatial frequency fr ranging from 0.02 [mm⁻¹] to 0.40 [mm⁻¹].

Specifically, the power spectral density Pr is calculated using the following equation.

$$P r ( u ) [ {μm}^{2} / {mm}^{- 1} ] = \frac{1}{L [ mm ]} \times {[ {\sum }_{x = 1}^{N} z ( x ) [ μm ] \times exp ( - 2 π i \times Δ L [ mm ] \times x \times u [ / mm ] ) \times Δ L [ mm ] ]}^{2} \qquad Equation 1$$

Equation 1 above is calculated in the x-axis direction of Y=a when the measurement points of the synthetic surface profile of the main surfaces 2 and 3 of the substrate 1 (measurement points in the inner region of a square having a side of 132 mm) are defined by an x-y coordinate system, and each variable is as follows.
Data interval (measurement range in x-axis direction): L [mm]
Number of data (number of measurement points in x-axis direction): N [pieces]
Data step width: ΔL [mm]=L/N
Height from reference surface at measurement coordinates (x,a): z (x) [μm]
Spatial frequency: u [/mm]
Power spectral density (PSD) at spatial frequency u: Pr (u) [μm²/mm⁻¹]

Each power spectral density Pr of the OK substrate and the NG substrate shown in FIG. 2 is calculated at an interval of the spatial frequency fr of 4.59×10⁻³ [mm⁻¹] when the data interval L is 132 [mm] and the number N of data is 228 [pieces].

The power spectral density Pr is preferably calculated at an interval of the spatial frequency fr of 1.0×10⁻² [mm⁻¹] or less. By using the power spectral density Pr calculated at the interval of the spatial frequency fr within this range, a substrate satisfying the desired overlay precision can be reliably obtained. The interval of the spatial frequency fr is more preferably 5.0×10⁻³ [mm⁻¹] or less.

The difference (PV value) between a maximum height and a minimum height in the inner region of the square having a side of 132 mm based on the center of the substrate in the synthetic surface profile of the substrate 1 is preferably 0.05 μm or less, more preferably 0.04 μm or less, and further preferably 0.03 μm or less.

It is also important for the substrate 1 to have high surface smoothness. The surface roughness of the main surfaces 2 and 3 of the substrate 1 on which a transfer pattern is to be formed is preferably 0.2 nm or less, more preferably 0.15 nm or less, and further preferably 0.1 nm or less in terms of root mean square roughness (RMS). Note that the surface smoothness can be measured using an atomic force microscope.

Moreover, the substrate 1 preferably has a high degree of rigidity in order to suppress deformation due to film stress of films (multilayer reflective film 4 and the like) formed thereon. Particularly, the substrate 1 preferably has a high Young's modulus of 65 GPa or more.

Next, a method of manufacturing the substrate 1 will be described. Note that this method of manufacturing the substrate 1 is an example and the embodiment is not limited to this method.

First, a substrate material is cut to a desired size (for example, dimension 152.4 mm×152.4 mm and thickness 6.35 mm). If necessary, end faces of this synthetic quartz glass substrate are chamfered and ground, and are further subjected to rough polishing and precision polishing with a polishing liquid containing cerium oxide abrasive grains. Subsequently, the surface profiles of the main surfaces of the substrate 1 are acquired, and a step of performing local processing on a relatively protruded region on the main surface is performed on each of the two main surfaces. Subsequently, the substrate is set on a carrier of a double-side polishing apparatus and is subjected to ultra-precision polishing under predetermined conditions. After completion of the ultra-precision polishing, the glass substrate is immersed in a dilute hydrofluoric acid solution for cleaning to remove colloidal silica abrasive grains. Subsequently, scrub cleaning is performed on the main surfaces and the end faces of the glass substrate, and then spin cleaning with pure water and spin drying are performed to obtain the substrate 1 having a polished surface.

Substrate with Multilayer Reflective Film and Method of Manufacturing the Same

FIG. 1 also illustrates a substrate 10 with a multilayer reflective film according to the embodiment of the present disclosure. As illustrated in FIG. 1, the substrate 10 with a multilayer reflective film includes a multilayer reflective film 4 provided on the one main surface 2 of the substrate 1 for a mask blank.

The substrate 10 with a multilayer reflective film according to the present embodiment includes a conductive film 5 provided on the other main surface 3 of the substrate 1 for a mask blank. In the substrate 10 with a multilayer reflective film according to the present embodiment, when a synthetic surface profile is produced from a surface profile of the multilayer reflective film 4 and a surface profile of the conductive film 5 in the inner region of the square having a side of 132 mm based on the center of the substrate 1 and the relationship between the spatial frequency fr[mm⁻¹] and the power spectral density Pr[μm²/(mm⁻¹)] is calculated from the synthetic surface profile, the relationship of Pr< (1.5141×10⁻⁶)×(fr^{-1.3717}) is satisfied at at least 75% or more of the spatial frequencies fr in the range of the spatial frequency fr from 0.02 [mm⁻¹] to 0.40 [mm⁻¹].

The synthetic surface profile is obtained by adding the surface profile of the multilayer reflective film 4, which is an in-plane distribution of a height from a reference surface which is the reference of the surface profile of the multilayer reflective film 4 to the surface of the multilayer reflective film 4 and the surface profile of the conductive film 5 which is an in-plane distribution of a height from a reference surface which is the reference of the surface profile of the conductive film 5 to the surface of the conductive film 5.

The reference surface of the multilayer reflective film 4 (or the conductive film 5) is a plane (least square plane) approximated by a least square method on the basis of height information of each measurement point of the multilayer reflective film 4 (or the conductive film 5) measured by the surface profile measuring apparatus. The power spectral density Pr is preferably calculated at an interval of the spatial frequency fr of 1.0×10⁻² [mm⁻¹] or less. The interval of the spatial frequency fr is more preferably 5.0×10⁻³ [mm⁻¹] or less.

As described above, the same method as that for the substrate 1 for a mask blank can be used for the substrate 10 with a multilayer reflective film. The reason for this is as follows. When thin films (the multilayer reflective film 4, the conductive film 5, and a protective film 6) are uniformly formed on the substrate 1, deformation due to film stress from each thin film occurs in the substrate 1. However, the distribution of the film stress acts such that these thin films substantially uniformly contract or expand the substrate 1. That is, the synthetic surface profile of the substrate 10 with a multilayer reflective film is a profile obtained by further adding a component of a quadric surface to the synthetic surface profile of the substrate 1 for a mask blank. However, when the main surface 3 (or the conductive film 5) of the substrate 10 with a multilayer reflective film is chucked by the exposure apparatus, the substrate 10 with a multilayer reflective film is deformed in a direction in which the components of the quadric surface of the synthetic surface profile are offset. Therefore, it is not necessary to consider the film stress of the thin film formed on the substrate 1. On the other hand, the spatial frequency of power spectral density corresponding to the component of the quadric surface generated by the stress of the thin film is much lower than 0.02 [mm⁻¹].

Thus, the same method as that for the substrate 1 for a mask blank can be used for the substrate 10 with a multilayer reflective film. The power spectral density Pr can also be calculated by using the above-described equation in a case where the measurement points of the synthetic surface profile of the multilayer reflective film 4 (the protective film 6 when the protective film 6 is formed) and the conductive film 5 in the substrate 10 with a multilayer reflective film are defined by the x-y coordinate system.

The multilayer reflective film 4 provides a reflective mask (not illustrated) with a function of reflecting EUV light, and is a multilayer film in which layers each including elements with different refractive indexes as main components are cyclically layered.

In general, a multilayer film in which a thin film (high refractive index layer) of a high refractive index material which is a light element or a compound thereof and a thin film (low refractive index layer) of a low refractive index material which is a heavy element or a compound thereof are alternately layered as one cycle and approximately 40 to 60 of the cycles are layered is used for the multilayer reflective film 4. The multilayer film may be formed by forming a layered structure with a high refractive index layer and a low refractive index layer, in which the high refractive index layer and the low refractive index layer are layered as one cycle in this order from the main surface 2 side of the substrate 1, and layering a plurality of cycles of the layered structure. The multilayer film may be formed by forming a layered structure with a low refractive index layer and a high refractive index layer, in which the low refractive index layer and the high refractive index layer are layered as one cycle in this order from the main surface 2 side of the substrate 1, and layering a plurality of cycles of the layered structure. Note that the outermost layer of the multilayer reflective film 4, that is, the surface layer of the multilayer reflective film 4 on the side opposite to the substrate 1 is preferably a high refractive index layer. When the multilayer film described above is formed by forming a layered structure with a high refractive index layer and a low refractive index layer, in which the high refractive index layer and the low refractive index layer are layered as one cycle in this order from the substrate 1, and layering a plurality of cycles of the layered structure, the uppermost layer is a low refractive index layer. In this case, when the low refractive index layer constitutes the outermost surface of the multilayer reflective film 4, the low refractive index layer is easily oxidized, and the reflectance of the reflective mask decreases. Therefore, the multilayer reflective film 4 is preferably formed by further forming a high refractive index layer on the uppermost low refractive index layer. On the other hand, when the multilayer film described above is formed by forming a layered structure with a low refractive index layer and a high refractive index layer, in which the low refractive index layer and the high refractive index layer are layered as one cycle in this order from the substrate 1 side and layering a plurality of cycles of the layered structure, since the uppermost layer is a high refractive index layer, the configuration may be left as it is.

In the present embodiment, a layer containing silicon (Si) is employed as the high refractive index layer. As the material containing Si, a Si compound containing Si, boron (B), carbon (C), nitrogen (N), and oxygen (O) can be used in addition to the material containing only Si. Using layers containing Si for a high refractive index layer makes it possible to produce a reflective mask for EUV lithography with excellent reflectance with respect to EUV light. In the present embodiment, a glass substrate is preferably used as the substrate 1. Si is also excellent in adhesion to the glass substrate. As the low refractive index layer, pure metal selected from molybdenum (Mo), ruthenium (Ru), rhodium (Rh), and platinum (Pt), or an alloy thereof is used. A Mo/Si cyclic layered film in which a Mo film and a Si film are alternately layered as one cycle and approximately 40 to 60 of cycles are layered is used for the multilayer reflective film 4 for EUV light having a wavelength of from 13 nm to 14 nm, for example. Note that the high refractive index layer, which is the uppermost layer of the multilayer reflective film 4, may be made of silicon (Si).

The reflectance of the multilayer reflective film 4 by itself is typically 65% or more, and the upper limit of the reflectance is typically 73%. Note that the film thickness and cycle of each constituent layer of the multilayer reflective film 4 may be appropriately selected according to an exposure wavelength, and are selected to satisfy the Bragg reflection law. A plurality of high refractive index layers and a plurality of low refractive index layers are present in the multilayer reflective film 4, but the film thicknesses of the high refractive index layers may differ from each other and the film thicknesses of the low refractive index layers may differ from each other. The film thickness of the Si layer of the outermost surface of the multilayer reflective film 4 can be adjusted within a range that does not result in a decrease in reflectance. The film thickness of the Si layer (high refractive index layer) of the outermost surface can be in the range from 3 nm to 10 nm.

A method of forming the multilayer reflective film 4 is known in the art. For example, each layer of the multilayer reflective film 4 can be formed using an ion beam sputtering method. In the case of the Mo/Si cyclic multilayer film described above, a Si film having a thickness of about 4 nm is first formed on the substrate 1 by the ion beam sputtering method using a Si target, for example. Subsequently, a Mo film having a thickness of about 3 nm is formed using a Mo target. With this Si film/Mo film as one cycle. 40 to 60 of the cycles are layered to form the multilayer reflective film 4 (outermost layer is the Si layer). Note that, for example, when the multilayer reflective film 4 includes 60 cycles, the number of steps increases compared to a case where the multilayer reflective film 4 includes 40 cycles, but the reflectance for EUV light can be increased. Furthermore, when forming the multilayer reflective film 4, the multilayer reflective film 4 is preferably formed by supplying krypton (Kr) ion particles from an ion source and performing ion beam sputtering.

The conductive film 5 generally has electrical properties (sheet resistance) required for electrostatic chucking, and the sheet resistance is typically 100Ω/(Ω/square) or less. The conductive film 5 can be formed by a magnetron sputtering method or an ion beam sputtering method using a target made of metal such as chromium (Cr) and tantalum (Ta) and an alloy, for example.

The thickness of the conductive film 5 is not particularly limited as long as the film can satisfactorily serve as a film for an electrostatic chuck. The thickness of the conductive film 5 ranges typically from 10 nm to 200 nm. The conductive film 5 also serves to adjust the stress on the main surface 3 side of the mask blank 20. That is, the conductive film 5 is adjusted to obtain a flat reflective mask blank 20 by balancing the stress from various films formed on the main surface 2 side.

The substrate 10 with a multilayer reflective film may also include the protective film 6 on the multilayer reflective film 4. To protect the multilayer reflective film 4 from dry etching and cleaning in a step of manufacturing the reflective mask to be described below, the protective film 6 can be formed on the multilayer reflective film 4 or in contact with the surface of the multilayer reflective film 4. The protective film 6 is made of a material having resistance to an etchant used when patterning an absorber film 11 and a cleaning liquid. Since the protective film 6 is formed on the multilayer reflective film 4, damage to the surface of the multilayer reflective film 4 can be suppressed when the reflective mask (EUV mask) is manufactured using the substrate 1 including the multilayer reflective film 4 and the protective film 6. Therefore, the reflectance characteristics of the multilayer reflective film 4 with respect to EUV light are improved. The protective film 6 is preferably made of, for example, pure Ru metal, or a material in which at least one or more elements selected from titanium (Ti), niobium (Nb), molybdenum (Mo), zirconium (Zr), yttrium (Y), boron (B), lanthanum (La), cobalt (Co), rhenium (Re), and rhodium (Ph) is contained in Ru. The protective film 6 can also be made of a silicon-based material such as silicon (Si), a material containing silicon (Si) and oxygen (O), a material containing silicon (Si) and nitrogen (N), or a material containing silicon (Si), oxygen (O), and nitrogen (N).

### Mask Blank and Method of Manufacturing the Same

FIG. 1 also illustrates the mask blank 20 according to the embodiment of the present disclosure. As illustrated in FIG. 1, the mask blank 20 is formed by providing a pattern forming thin film (absorber film 11) on the multilayer reflective film 4 (on the protective film 6 when the protective film 6 is provided) of the substrate 10 with a multilayer reflective film.

The mask blank 20 according to the present embodiment includes the pattern forming thin film (absorber film 11) on the one main surface 2 of the substrate 1 for a mask blank, and the conductive film 5 provided on the other main surface 3 thereof. In the mask blank 20 according to the present embodiment, when a synthetic surface profile is produced from a surface profile of the absorber film 11, which is a pattern forming thin film, and the surface profile of the conductive film 5 in the inner region of the square having a side of 132 mm based on the center of the substrate 1 and the relationship between the spatial frequency fr[mm⁻¹] and the power spectral density Pr[μm²/(mm⁻¹)] is calculated from the synthetic surface profile, the relationship of Pr< (1.5141×10⁶)×(fr^{-1.3717}) is satisfied at at least 75% or more of the spatial frequencies fr in the range of the spatial frequency fr from 0.02 [mm⁻¹] to 0.40 [mm⁻¹].

The synthetic surface profile is obtained by adding the surface profile of the absorber film 11, which is an in-plane distribution of a height from a reference surface which is the reference of the surface profile of the absorber film 11 to the surface of the absorber film 11 and the surface profile of the conductive film 5 which is the in-plane distribution of the height from the reference surface which is the reference of the surface profile of the conductive film 5 to the surface of the conductive film 5.

The reference surface of the absorber film 11 (or the conductive film 5) is a plane (least square plane) approximated by a least square method on the basis of height information of each measurement point of the absorber film 11 (or the conductive film 5) measured by the surface profile measuring apparatus. The power spectral density Pr is preferably calculated at an interval of the spatial frequency fr of 1.00×10⁻² [mm⁻¹] or less. The interval of the spatial frequency fr is more preferably 5.0×10⁻³ [mm⁻¹] or less.

As described above with respect to the substrate 10 with a multilayer reflective film, the same method as that for the substrate 1 for a mask blank can be used for the mask blank 20. The power spectral density Pr can also be calculated by using the above-described equation in a case where the measurement points of the synthetic surface profile of the absorber film 11 and the conductive film 5 in the mask blank 20 are defined by the x-y coordinate system.

The absorber film 11 has a function of absorbing EUV light which is exposure light, and may have a desired reflectance difference between reflected light by the above multilayer reflective film 4 and protective film 6 and reflected light by the absorber pattern in the reflective mask manufactured using the mask blank 20.

For example, the absolute reflectance of the absorber film 11 with respect to EUV light is set from 0.1% to 40%. In addition to the above reflectance difference, the absorber film 11 may have a desired phase difference between the reflected light by the above multilayer reflective film 4 and protective film 6 and the reflected light by the absorber pattern. When the desired phase difference is provided between the reflected lights to improve the contrast of reflected light of a reflective mask that is obtained, the phase difference is preferably set in the range from 130° to 230°, the absolute reflectance of the absorber film 11 is preferably set in the range from 1.5% to 30%, and the relative reflectance of the absorber film 11 (reflectance when the reflectance of the multilayer reflective film 4 with respect to the EUV light is 100%) is preferably set in the range from 2% to 40%.

The above absorber film 11 may have a single layer structure or a layered structure. In the case of the layered structure, a layered film of the same material or a layered film of different materials may be used. The material and composition of the layered film may be changed stepwise and/or continuously in a film thickness direction.

The material of the above absorber film 11 is not particularly limited, but preferably contains a metal element. For example, pure tantalum (Ta) may be used, or a material containing Ta as a main component, which has a function of absorbing EUV light, may be used.

A material in which at least one element selected from tellurium (Te), antimony (Sb), platinum (Pt), iodide (I), bismuth (Bi), iridium (Ir), osmium (Os), tungsten (W), rhenium (Re), tin (Sn), indium (In), polonium (Po), iron (Fe), gold (Au), mercury (Hg), gallium (Ga), and aluminum (Al) is contained in tantalum (Ta) may be used for the absorber film 11. The absorber film 11 may also be made of a material containing tantalum (Ta) and iridium (Ir). On the other hand, the absorber film 11 may be made of a material containing ruthenium (Ru) and chromium (Cr). The absorber film 11 may be made of a material in which at least one element selected from nitrogen (N), oxygen (O), boron (B), and carbon (C) is contained in ruthenium (Ru) and chromium (Cr).

As the pattern forming thin film, an etching mask film may also be provided on the absorber film 11. The mask blank 20 in this case includes the pattern forming thin film (the absorber film 11 and the etching mask film) on the one main surface 2 of the substrate 1 for a mask blank, and the conductive film 5 provided on the other main surface 3 thereof. In the mask blank 20 in this case, when a synthetic surface profile is produced from a surface profile of the etching mask film, which is a pattern forming thin film, and the surface profile of the conductive film 5 in the inner region of the square having a side of 132 mm based on the center of the substrate 1 and the relationship between the spatial frequency fr[mm⁻¹] and the power spectral density Pr[μm²/(mm⁻¹)] is calculated from the synthetic surface profile, the relationship of Pr< (1.5141×10⁻⁶)×(fr^{-1.3717}) is satisfied at at least 75% or more of the spatial frequencies fr in the range of the spatial frequency fr from 0.02 [mm⁻¹] to 0.40 [ mm⁻¹].

The synthetic surface profile is obtained by adding the surface profile of the etching mask film, which is an in-plane distribution of a height from a reference surface which is the reference of the surface profile of the etching mask film to the surface of the etching mask film and the surface profile of the conductive film 5 which is the in-plane distribution of the height from the reference surface which is the reference of the surface profile of the conductive film 5 to the surface of the conductive film 5.

The reference surface of the etching mask film (or the conductive film 5) is a plane (least square plane) approximated by a least square method on the basis of height information of each measurement point of the etching mask film (or the conductive film 5) measured by the surface profile measuring apparatus. The power spectral density Pr is preferably calculated at an interval of the spatial frequency fr of 1.00×10⁻² [mm⁻¹] or less. The interval of the spatial frequency fr is more preferably 5.0×10⁻³ [mm⁻¹] or less.

As described above with respect to the substrate 10 with a multilayer reflective film, the same method as that for the substrate 1 for a mask blank can be used for the mask blank 20. The power spectral density Pr can be calculated by using the above-described equation in a case where the measurement points of the synthetic surface profile of the etching mask film and the conductive film 5 in the mask blank 20 are defined by the x-y coordinate system.

The material of the etching mask film is not particularly limited, but a material having a high etching selectivity of the absorber film 11 with respect to the etching mask film (etching rate of the absorber film 11/etching rate of the etching mask film) is preferably used.

The etching mask film may be made of a material containing at least one element selected from chromium (Cr), tantalum (Ta), and silicon (Si). A material obtained by adding at least one element selected from N, O, C, and H to these materials may also be used.

The method of manufacturing the mask blank 20 of the present disclosure includes a step of providing a pattern forming thin film (the absorber film 11, or the absorber film 11 and an etching mask film when the etching mask film is provided) on the protective film 6 of the substrate 10 with a multilayer reflective film described above. In the method of manufacturing the mask blank 20 of the present disclosure, in the step of forming the absorber film 11, the absorber film 11 is preferably formed by a reactive sputtering method using a sputtering target made of a material contained in the absorber film 11 and is preferably formed so as to contain a component contained in an atmospheric gas when the reactive sputtering is performed.

When the mask blank 20 including the etching mask film is manufactured, in addition to the above-described step of forming the absorber film 11, in the step of forming the etching mask film, the etching mask film is preferably formed by a reactive sputtering method using a sputtering target made of a material contained in the etching mask film and is preferably formed so as to contain a component contained in an atmospheric gas when reactive sputtering is performed.

As described above, the substrate 1 for a mask blank, the substrate 10 with a multilayer reflective film, and the mask blank 20 according to the embodiment of the present disclosure make it possible to produce a transfer mask that can satisfy desired overlay precision.

### Method of Manufacturing Transfer Mask

The method of manufacturing a transfer mask of the present disclosure includes a step of patterning the absorber film (pattern forming thin film) 11 in the above mask blank 20 to form an absorber film (absorber pattern) having a transfer pattern on the multilayer reflective film 4 described above or on the protective film 6 described above. When the mask blank 20 includes an etching mask film, the absorber film (absorber pattern) having the transfer pattern is formed on the multilayer reflective film 4 described above or on the protective film 6 described above by patterning the etching mask film and then patterning the absorber film 11. When the transfer mask of the present embodiment manufactured in this way is exposed with exposure light such as EUV light, the exposure light is absorbed in a portion of the surface of the transfer mask where the absorber film 11 is present, and is reflected by the exposed protective film 6 and multilayer reflective film 4 in the other portion where the absorber film 11 has been removed, so that the transfer mask can be used as a transfer mask for lithography.

The transfer mask of the present disclosure includes an absorber pattern on the multilayer reflective film 4 (or on the protective film 6), so that a predetermined pattern can be transferred in a transfer object by using EUV light.

### Method of Manufacturing Semiconductor Device

The transfer mask manufactured by the method of manufacturing the transfer mask described above is set on a mask stage of the exposure apparatus, and a transfer pattern of the transfer mask is pattern-transferred onto a semiconductor substrate by a lithography method, so that a semiconductor device in which various transfer patterns and the like are formed on a transfer object such as a semiconductor substrate can be manufactured.

That is, the present disclosure is a method of manufacturing a semiconductor device including a step of forming the transfer pattern on the transfer object by performing a lithography process using the exposure apparatus by using the transfer mask described above.

According to the method of manufacturing a semiconductor device of the present disclosure, exposure transfer can be performed using a transfer mask satisfying desired overlay precision, and positional deviation of the transfer mask during pattern transfer can be suppressed, so that a semiconductor device having a fine and highly precise transfer pattern can be manufactured.

Hereinafter, the substrate 1 for a mask blank, the substrate 10 with a multilayer reflective film, the mask blank 20, and the reflective mask in Examples 1 to 3 of the present disclosure and a substrate for a mask blank, a substrate with a multilayer reflective film, a mask blank, and a reflective mask in Comparative Examples 1 to 3 will be described.

### Manufacture of Substrate for Mask Blank

The substrate 1 for a mask blank in Examples 1 to 3 and the substrate for a mask blank in Comparative Examples 1 to 3 were manufactured as follows.

First, a SiO₂—TiO₂-based glass substrate having a size of 152 mm×152 mm and a thickness of 6.35 mm was prepared, and front and back surfaces of the glass substrate was polished stepwise with cerium oxide abrasive grains or colloidal silica abrasive grains by using a double-side polishing apparatus and then subjected to surface treatment with low-concentration silicofluoric acid.

Measurement points were set in a grid pattern at 256 points×256 points within a measurement region of 148 mm×148 mm on the front and back surfaces of the glass substrate, and surface profiles (surface conformation, flatness) and TTV (plate thickness variation) were measured by a wavelength shift interferometer using a wavelength-modulated laser. The measurement results of the front surface profile (flatness) of the surface of the glass substrate were stored in a computer as height information with respect to a reference surface for each measurement point and compared with a reference value of 50 nm (protruded shape) of the front surface flatness and a reference value of 50 nm of the back surface flatness required for the glass substrate, and the difference (required removal amount) was calculated by the computer.

Subsequently, processing conditions for local surface processing according to the required removal amount were set for each processing spot-shaped region in the surface of the glass substrate. A dummy substrate is used in advance and is processed at a spot without moving the substrate for a certain period of time in the same manner as in actual processing, the shape thereof is measured by the same measuring instrument as an instrument for measuring the surface profile of the above front and back surfaces, and a processing volume of the spot per unit time is calculated. Subsequently, a scanning speed for raster-scanning the glass substrate was determined according to the required removal amount obtained from information on the spot and information on the surface profile of the glass substrate.

Local surface processing was performed by using a substrate finishing apparatus with a magnetic viscoelastic fluid and by a magneto rheological finishing (MRF) processing method according to the set processing conditions so that the flatness of the front and back surfaces of the glass substrate is equal to or less than the above reference value, thereby adjusting the surface profile. The magnetic viscoelastic fluid used at this time contained an iron component, and an alkaline aqueous solution containing about 2 wt % of cerium oxide as a polishing agent was used for a polishing slurry. Subsequently, the glass substrate was immersed in a cleaning tank containing a hydrochloric acid aqueous solution (temperature of about 25° C.) having a concentration of about 10% for about 10 minutes, and then rinsed with pure water and dried with isopropyl alcohol (IPA).

Subsequently, the front and back surfaces of the glass substrate were subjected to double-side polishing by using a double-side polishing apparatus under polishing conditions for maintaining or improving the surface profile of the surface of the glass substrate.

Subsequently, the glass substrate was washed with an alkaline aqueous solution (NaOH).

For the substrate 1 for a mask blank in each of Examples 1 to 3 and the substrate for a mask blank in each of Comparative Examples 1 to 3 obtained in this way, the surface profiles of the two main surfaces 2 and 3 were measured with a surface profile measuring apparatus (UltraFlat200M available from Corning Tropel Corporation). As a result, in any of the two main surfaces 2 and 3 of the substrate 1 for a mask blank in each of Examples 1 to 3 and the two main surfaces of the substrate for a mask blank in each of Comparative Examples 1 to 3, the difference (flatness) between the maximum height and the minimum height in the inner region of the square having a side of 132 mm based on the center of the substrate 1 was 0.05 μm or less.

For the substrate for a mask blank in each of Examples 1 to 3 and the substrate for a mask blank in each of Comparative Examples 1 to 3, synthetic surface profiles were produced in the inner region of the square having a side of 132 mm based on the center of the substrate 1. As a result, in any of the synthetic surface profiles, the difference (PV value) between the maximum height and the minimum height in the inner region of the square having a side of 132 mm based on the center of the substrate was 0.05 μm or less.

Subsequently, for the substrate 1 for a mask blank in each of Examples 1 to 3, the relationship between the spatial frequency fr[mm⁻¹] and the power spectral density Pr[μm²/(mm⁻¹)] was calculated from the synthetic surface profile. Also in Comparative Examples 1 to 3, the relationship between the spatial frequency fr[mm⁻¹] and the power spectral density Pr[μm²/(mm⁻¹)] was calculated from the synthetic surface profile. The power spectral density Pr in each of Examples 1 to 3 and each of Comparative Examples 1 to 3 was calculated at an interval of the spatial frequency fr of 4.59×10⁻³ [mm⁻¹] when the data interval L is 132 [mm] and the number N of data is 228 [pieces].

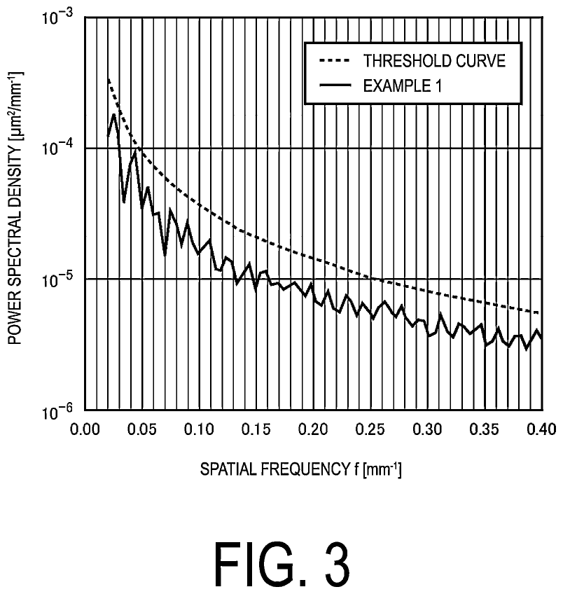

FIG. 3 to 5 are graphs showing curves of power spectral density in the substrate for a mask blank of Examples 1-3 and threshold curves with respect to spatial frequency.

As shown in FIG. 3, in Example 1, all the power spectral densities had values below the threshold curve (curve of Pr=(1.5141×10⁻⁶)×(fr^{-1.3717})) in the range of the spatial frequency fr from 0.02 [mm⁻¹] to 0.40 [mm⁻¹]. That is, in Example 1, in the range of the spatial frequency fr from 0.02 [mm⁻¹] to 0.40 [mm⁻¹], 100% of the spatial frequencies fr satisfied the relationship of Pr< (1.5141×10⁻⁶)×(fr^{-1.3717}), which satisfied the condition of 75% or more.

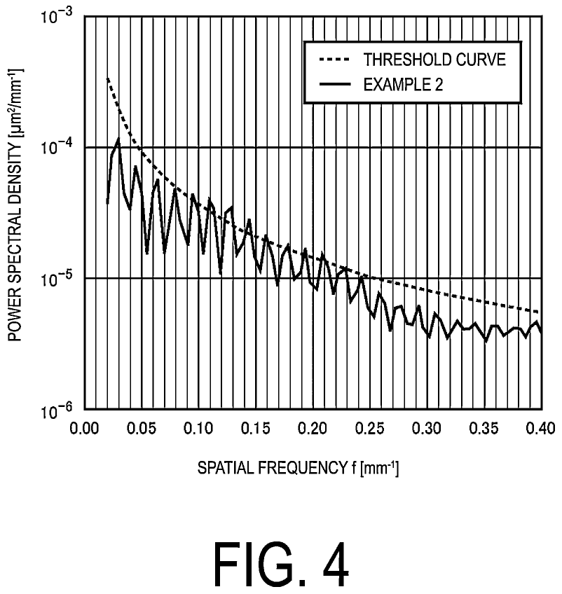

As shown in FIG. 4, in Example 2, 86% of the power spectral density had a value below the threshold curve in the range of the spatial frequency fr from 0.02 [mm⁻¹] to 0.40 [mm⁻¹]. That is, in Example 2, the relationship of Pr< (1.5141×10⁻⁶)×(fr^{-1.3717}) was satisfied at 86% of the spatial frequencies fr, and the condition of 75% or more was satisfied.

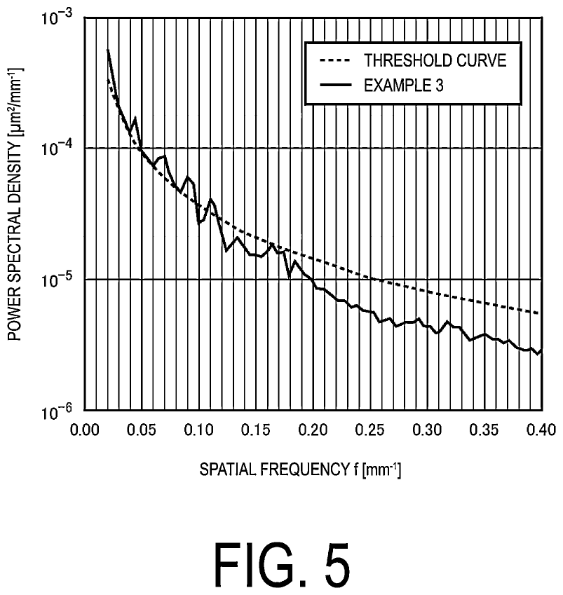

As shown in FIG. 5, in Example 3, 78% of the power spectral density had a value below the threshold curve in the range of the spatial frequency fr from 0.02 [mm⁻¹] to 0.40 [mm⁻¹]. That is, in Example 3, the relationship of Pr< (1.5141×10⁻⁶)×(fr^{-1.3717}) was satisfied at 78% of the spatial frequencies fr, and the condition of 75% or more was satisfied.

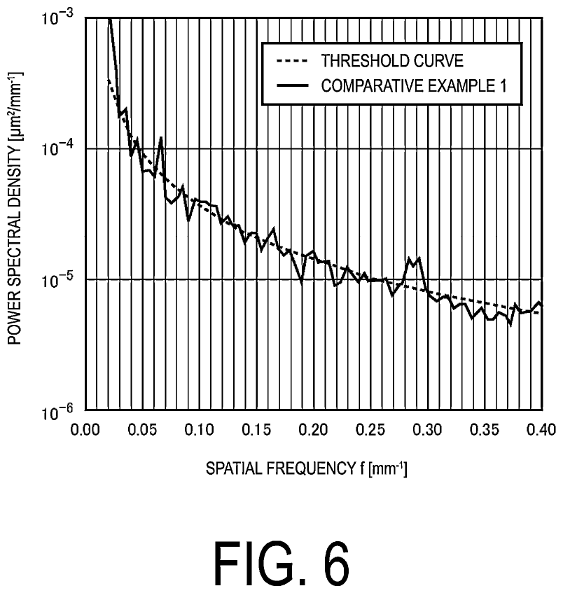

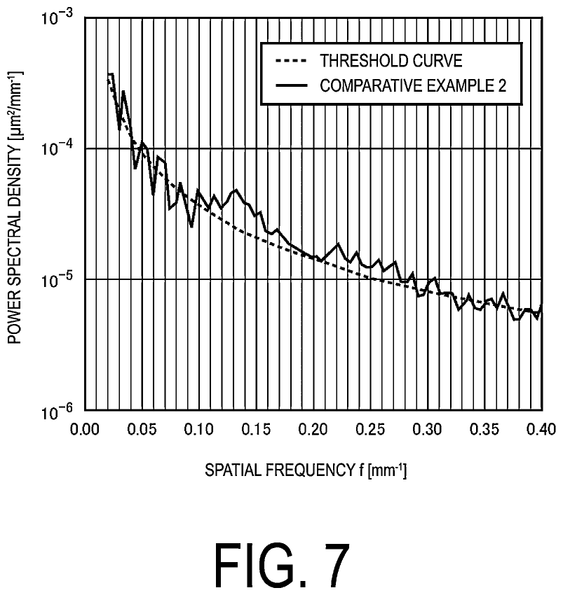

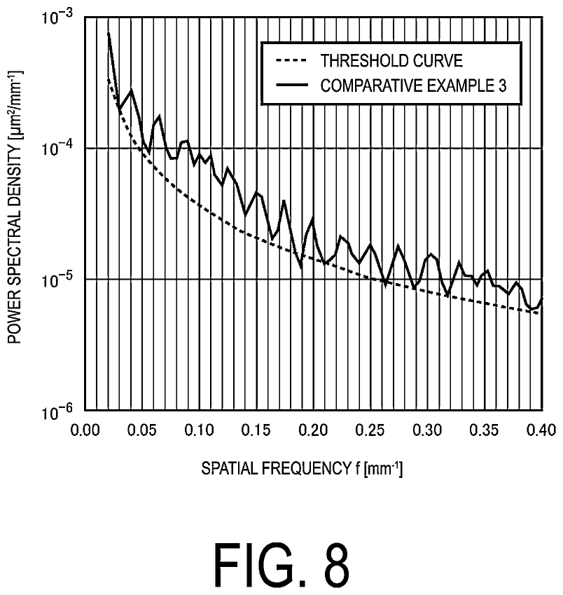

On the other hand, FIGS. 6 to 8 are graphs showing curves of power spectral density in the substrates for a mask blank of Comparative Examples 1 to 3 and threshold curves with respect to spatial frequency. As shown in FIG. 6 to 8, in Comparative Examples 1 to 3, only 44%, 17%, and 2% of the power spectral densities had values below the threshold curve (curve of Pr=(1.5141×10⁶)×(fr^{-1.3717})) in the range of the spatial frequency fr from 0.02 [mm⁻¹] to 0.40 [mm⁻¹]. That is, none of Comparative Examples 1 to 3 satisfied the relationship Pr< (1.5141×10⁻⁶)×(fr^{-1.3717}) at 75% or more of the spatial frequencies fr in the range of the spatial frequency fr from 0.02 [mm⁻¹] to 0.40 [mm⁻¹].

Manufacture of Substrate with Multilayer Reflective Film

Subsequently, using the substrate 1 for a mask blank in each of Examples 1 to 3 described above and the substrate for a mask blank in each of Comparative Examples 1 to 3 described above, the substrate 10 with a multilayer reflective film in each of Examples 1 to 3 and the substrate with a multilayer reflective film in each of Comparative Examples 1 to 3 were produced.

The substrate 10 with a multilayer reflective film in each of Examples 1 to 3 was formed as follows. That is, using a Mo target and a Si target, an Mo layer (low refractive index layer having a thickness of 2.8 nm) and a Si layer (high refractive index layer having a thickness of 4.2 nm) were alternately layered (the number of layered layers was 40 pairs) by an ion beam sputtering method to respectively form the multilayer reflective film 4 on the substrate 1 for a mask blank described above.

After the multilayer reflective film 4 is formed, the protective film 6 (Ru film having a thickness of 2.5 nm) was further continuously formed on the multilayer reflective film 4 by a DC sputtering method. Subsequently, the conductive film 5 (TaBN film) was formed on the main surface 3 by a sputtering method to produce the substrate 10 with a multilayer reflective film.

In this way, the substrate 10 with a multilayer reflective film in each of Examples 1 to 3 was manufactured. Also in each of Comparative Examples 1 to 3, the substrate with a multilayer reflective film was manufactured in the same manner.

For the substrate 10 with a multilayer reflective film in each of Examples 1 to 3 and the substrate with a multilayer reflective film in each of Comparative Examples 1 to 3 obtained in this way, synthetic surface profiles were respectively obtained in the same manner as for the substrate 1 for a mask blank in each of Examples 1 to 3 and the substrate for a mask blank in each of Comparative Examples 1 to 3. That is, in each of Examples 1 to 3, the synthetic surface profile was produced from the surface profile of the protective film 6 and the surface profile of the conductive film 5 in the inner region of the square having a side of 132 mm based on the center of the substrate 1, and the relationship between the spatial frequency fr[mm⁻¹] and the power spectral density Pr[μm²/(mm⁻¹)] was calculated with substrate deformation components caused by film stress removed from the synthetic surface profile. The same calculation was performed for the substrate with a multilayer reflective film in each of Comparative Examples 1 to 3.

As a result, in the substrate 10 with a multilayer reflective film in each of Examples 1 to 3, the relationship of Pr< (1.5141×10⁻⁶)×(fr^{-1.3717}) was satisfied at 75% or more of the spatial frequencies fr in the range of the spatial frequency fr from 0.02 [mm⁻¹] to 0.40 [mm⁻¹].

On the other hand, in the substrate with a multilayer reflective film in each of Comparative Examples 1 to 3, the relationship of Pr< (1.5141×10⁶)×(fr^{-1.3717}) was not satisfied at 75% or more of the spatial frequencies fr in the range of the spatial frequency fr from 0.02 [mm⁻¹] to 0.40 [mm⁻¹].

### Manufacture of Mask Blank

Subsequently, the absorber film 11 (TaBN film having a thickness of 55 nm) was formed on the surface of the protective film 6 of the substrate 10 with a multilayer reflective film in each of Examples 1 to 3 described above by a DC magnetron sputtering method.

In this way, the mask blank 20 in each of Examples 1 to 3 was obtained. Also in each of Comparative Examples 1 to 3, the mask blank was produced in the same manner.

For the mask blank 20 in each of Examples 1 to 3 obtained in this way, a synthetic surface profile was obtained in the same manner as for the substrate 1 for a mask blank. That is, the synthetic surface profile was produced from the surface profile of the absorber film 11, which is a pattern forming thin film, and the surface profile of the conductive film 5 in the inner region of the square having a side of 132 mm based on the center of the substrate 1, and the relationship between the spatial frequency fr[mm⁻¹] and the power spectral density Pr[μm²/(mm⁻¹)] was calculated with substrate deformation components caused by film stress removed from the synthetic surface profile. Also in Comparative Examples 1 to 3, the relationship was calculated in the same manner.

As a result, in the mask blank 20 in each of Examples 1 to 3, the relationship of Pr< (1.5141×10⁻⁶)×(fr^{-1.3717}) was satisfied at 75% or more of the spatial frequencies fr in the range of the spatial frequency fr from 0.02 [mm⁻¹] to 0.40 [mm⁻¹].

On the other hand, the mask blank 20 in each of Comparative Examples 1 to 3, the relationship of Pr< (1.5141×10⁶)×(fr^{-1.3717}) was not satisfied at 75% or more of the spatial frequencies fr in the range of the spatial frequency fr from 0.02 [mm⁻¹] to 0.40 [mm⁻¹].

### Production of Reflective Mask

A resist was applied to the surface of the absorber film 11 of the reflective mask blank 20 in each of Examples 1 to 3 by a spin coating method to form a resist film having a thickness of 100 nm. Subsequently, a desired pattern was written, and the resist film was developed to form a resist pattern. Using the resist pattern as a mask, the absorber film 11 was patterned by predetermined dry etching to form an absorber pattern on the protective film 6.

Subsequently, the resist film was removed, and chemical cleaning was performed to produce the reflective mask in each of Examples 1 to 3. Also in each of Comparative Examples 1 to 3, the reflective mask was produced in the same manner.

### Manufacture of Semiconductor Device

As a result of performing pattern transfer onto a semiconductor substrate through an exposure apparatus using EUV light as exposure light by using the reflective mask obtained in each of Examples 1 to 3, it was confirmed that a pattern satisfying desired overlay precision that is required and having high positional precision without causing positional deviation can be formed.

On the other hand, as a result of performing pattern transfer onto a semiconductor substrate through an exposure apparatus using EUV light as exposure light by using the reflective mask produced in each of Comparative Examples 1 to 3, desired overlay precision that is required was not satisfied, positional deviation occurred in the transferred pattern, and pattern transfer with high precision could not be performed.

### DESCRIPTION OF REFERENCE NUMERALS

1 Substrate for mask blank
2 (One) main surface
3 (Other) main surface
4 Multilayer reflective film
5 Conductive film
6 Protective film
10 Substrate with multilayer reflective film
11 Absorber film (pattern forming thin film)
20 Mask blank

1. A substrate for a mask blank, the substrate comprising
one main surface and other main surface opposing the one main surface,
wherein a value of a power spectral density Pr[μm²/(mm⁻¹)] is below approximately (1.5141×10⁻⁶)×(fr^{-1.3717}) for is satisfied at least 75% or more of the spatial frequencies fr in a range of the spatial frequency fr from 0.02 [mm⁻¹] to 0.40 [mm⁻¹], where the power spectral density Pr is calculated from a synthetic surface profile determined based upon surface profiles of each of the one main surface and other main surface in an area comprising an inner region of a square having a side of 132 mm and a center at a center of the substrate.

2. The substrate for a mask blank according to claim 1,
wherein the synthetic surface profile is determined by adding in-plane height values from a reference surface from both the surface profile of the one main surface to the one main surface, and the surface profile of the other main surface.

3. The substrate for a mask blank according to claim 1,
wherein the power spectral density Pr is calculated at an interval of the spatial frequency fr of 1.0×10⁻² [mm⁻¹] or less.

4. The substrate for a mask blank according to claim 1 further comprising
a multilayer reflective film provided above the one main surface of the substrate upon which the power spectral density Pr is calculated.

5. A substrate with a multilayer reflective film, the substrate comprising:
a substrate having one main surface and other main surface opposing the one main surface,
a multilayer reflective film provided above the one main surface of the substrate; and
a conductive film provided above the other main surface of the substrate,
wherein a value of a power spectral density Pr[μm²/(mm⁻¹)] is below approximately (1.5141×10⁻⁶)×(fr^{-1.3717}) for at least 75% or more of the spatial frequencies fr in a range of the spatial frequency fr from 0.02 [mm⁻¹] to 0.40 [mm⁻¹], where the power spectral density Pr is calculated from a synthetic surface profile determined based upon surface profiles of each of a surface of the multilayer reflective film and a surface of the conductive film in an area comprising an inner region of a square having a side of 132 mm and a center at a center of the substrate.

6. The substrate with a multilayer reflective film according to claim 5,
wherein the synthetic surface profile is determined by adding in-plane height values from a reference surface from both the surface profile of the multilayer reflective film and the surface profile of the conductive film.

7. The substrate with a multilayer reflective film according to claim 5,
wherein the power spectral density Pr is calculated at an interval of the spatial frequency fr of 1.0×10⁻² [mm⁻¹] or less.

8. A mask blank comprising
the substrate with a multilayer reflective film according to claim 5, and
a pattern forming thin film provided above the multilayer reflective film of the substrate with a multilayer reflective film.

9. A mask blank comprising:
a substrate having one main surface and other main surface opposing the one main surface;
a pattern forming thin film provided above the one main surface of the substrate; and
a conductive film provided above the other main surface of the substrate,
wherein a value of a power spectral density Pr[μm²/(mm⁻¹)] is below approximately calculated from the synthetic surface profile, a relationship of Pr (1.5141×10⁻⁶)×(fr^{-1.3717}) for at least 75% or more of the spatial frequencies fr in a range of the spatial frequency fr from 0.02 [mm⁻¹] to 0.40 [mm⁻¹], where the power spectral density Pr is calculated from a synthetic surface profile determined based upon surface profiles of each of a surface of the pattern forming thin film and a surface of the conductive film in an area comprising an inner region of a square having a side of 132 mm and a center at a center of the substrate.

10. The mask blank according to claim 9,
wherein the synthetic surface profile is determined by adding in-plane height values from a reference surface from both the surface profile of the pattern forming thin film and the surface profile of the conductive film.

11. The mask blank according to claim 9,
wherein the power spectral density Pr is calculated at an interval of the spatial frequency fr of 1.0×10⁻² [mm⁻¹] or less.

12. The mask blank according to claim 9 comprising
a multilayer reflective film between the one main surface and the pattern forming thin film.

13. A transfer mask, comprising:
a transfer pattern formed in the pattern forming thin film of the mask blank according to claim 9.

14. (canceled)

15. The mask blank according to claim 12,
wherein the pattern forming thin film includes at least one of an absorber film and an etching mask film provided above an absorber film.

16. The substrate with a multilayer reflective film according to claim 6,
wherein the power spectral density Pr is calculated at an interval of the spatial frequency fr of 1.0×10⁻² or less.

17. The mask blank according to claim 10,
wherein the power spectral density Pr is calculated at an interval of the spatial frequency fr of 1.0×10⁻² or less.

18. The mask blank according to claim 17,
wherein the pattern forming thin film includes at least one of an absorber film and an etching mask film provided above an absorber film.

19. The mask blank according to claim 10 comprising a multilayer reflective film between the one main surface and the pattern forming thin film.

20. The mask blank according to claim 11 comprising a multilayer reflective film between the one main surface and the pattern forming thin film.
